(19) United States
(12) Patent Application Publication
(10) Pub. No.: US 2026/0282461 A1
(43) Pub. Date: Sep. 17, 2026

(54) LATERALLY DIFFUSED METAL OXIDE SEMICONDUCTOR

(71) Applicant: UNITED MICROELECTRONICS CORP., Hsin-Chu City (TW)

(72) Inventors: Te-Chi Yen, Tainan City (TW); Ling-Chun Chou, Tainan City (TW); Yu-Hung Chang, Tainan City (TW); Pin-Tseng Chen, Kaohsiung City (TW); Kun-Hsien Lee, Tainan City (TW)

(73) Assignee: UNITED MICROELECTRONICS CORP., Hsin-Chu City (TW)

(21) Appl. No.: 19/086,122

(22) Filed: Mar. 20, 2025

(30) Foreign Application Priority Data
Mar. 13, 2025 (CN) 202510294381.7

(51) Int. Cl. H10D 62/10; H10D 30/60; H10D 30/65; H10D 64/66

(52) U.S. Cl. CPC H10D 62/102; H10D 30/611; H10D 30/655; H10D 62/115; H10D 62/124; H10D 64/661

(57) ABSTRACT

An LDMOS features a semiconductor substrate with adjacent first and second wells of differing doping types. The second well is isolated from a third well by a first STI, with the bottom of the first STI being in direct contact with a native region of the semiconductor substrate. A gate pattern is formed on the semiconductor substrate, vertically overlapping both the first and second wells. Additionally, a dummy pattern is positioned atop the first STI, and a source doped region is formed in the first well on one side of the gate pattern, while a drain doped region is positioned within the third well.

### BACKGROUND OF THE INVENTION

### 1. Field of the Invention

The present invention generally relates to a laterally diffused metal-oxide semiconductor (LDMOS) device, and more specifically, to an LDMOS having a dummy pattern and a native region in the substrate.

### 2. Description of the Prior Art

A laterally diffused metal-oxide semiconductor (LDMOS) device is a type of power field-effect transistor, primarily utilized in high-voltage, high-power radio frequency applications, such as power amplifiers in base stations for mobile communication systems. It is renowned for its ability to maintain stable operation and high reliability even under extremely high breakdown voltages. A key feature of LDMOS is the presence of a thick oxide layer beneath the gate region near the drain terminal, such as a field oxide layer or shallow trench isolation (STI), which effectively prevents breakdown in this region, a site that is vulnerable to electric field concentration at the surface of drift region at the end of the channel. Furthermore, by controlling the doping concentrations of both the lateral and vertical PN junctions as well as the thickness of the drift region in the LDMOS, the drift region can be completely depleted before the lateral junction reaches its critical breakdown voltage, thereby reducing the surface electric field (RESURF) and significantly enhances the breakdown voltage at the drain terminal.

Typically, the breakdown voltage (BVD) of an LDMOS can be improved by adjusting the doping levels of the P-type and N-type wells that form the internal PN junctions. However, in cases where the LDMOS acts as a parasitic element, its well regions often share the well regions of other active elements, which constrains the flexibility to modify the doping conditions of the well. As a result, additional photomasks or ion implantation steps must be incorporated during fabrication to enhance the breakdown voltage, inevitably increasing production costs. Consequently, those of skilled in the field are continuously striving to refine the structure of existing LDMOS devices to address these challenges and achieve the desired performance improvements.

### SUMMARY OF THE INVENTION

In light of the shortcomings of the prior art, the present invention hereby introduces a laterally diffused metal-oxide semiconductor (LDMOS) device, characterized by a shallow trench isolation (STI) positioned on the drift region, which effectively divides the drift region into two wells. A dummy pattern is placed on the STI, with its bottom surface in direct contact with a native region of the substrate. This innovative configuration enhances the breakdown voltage (BVD) of the device, while eliminating the need for additional photomasks or ion implantation steps.

The objective of the present invention is to provide a lateral diffusion metal-oxide semiconductor device, including: a semiconductor substrate, comprising a first well, a second well and a third well, wherein the first well and the second well are adjacent to each other in a first direction and have different doping types; a first shallow trench isolation, positioned in the semiconductor substrate and separating the second well from the third well, and both the second well and the third well share the same doping type, wherein the first shallow trench isolation directly contacts both the second well and the third well on either side in the first direction, with a bottom of the first shallow trench isolation being in direct contact with a native region of the semiconductor substrate; a gate pattern, positioned on the semiconductor substrate and vertically overlaps both the first well and the second well; a dummy pattern, positioned atop the first S shallow trench isolation; a source doped region, positioned in the first well on one side of the gate pattern; and a drain doped region, positioned on the third well.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view of the LDMOS taken along the section line A-A’ in FIG. 1 in accordance with the embodiment of present invention; and

FIG. 2 is a schematic layout diagram of the LDMOS in accordance with the embodiment of present invention.

It should be noted that all the figures are diagrammatic. Relative dimensions and proportions of parts of the drawings have been shown exaggerated or reduced in size, for the sake of clarity and convenience in the drawings. The same reference signs are generally used to refer to corresponding or similar features in modified and different embodiments.

### DETAILED DESCRIPTION

Reference will now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of the present disclosure, modifications, equivalents, or improvements to the present disclosure are understandable to those skilled in the art and are intended to be encompassed within the scope of the present disclosure.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something). Further, spatially relative terms, such as “beneath,” “below,” “lower,” “above,” “upper,” and the like, may be used herein for ease of description to describe one element or feature relationship to another element(s) or feature(s) as illustrated in the figures.

As used herein, the term “layer” refers to a material portion including a region with a thickness. A layer can extend over the entirety of an underlying or overlying structure, or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductor and contact layers (in which contacts, interconnect lines, and/or through holes are formed) and one or more dielectric layers.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. Additionally, the term "based on" may be understood as not necessarily intended to convey an exclusive set of factors, but may allow for the presence of other factors not necessarily expressly described, again depending at least in part on the context.

It will be further understood that the terms “includes,” “including,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein in the description of the invention, the “N” and “P” designations, as in “N type” and “P type”, are used in the common manner to designate donor and acceptor type impurities which promote electron and hole type carriers respectively as the majority carriers. The “++” symbol, when used as a suffix with an impurity type should be interpreted to mean that the doping concentration of that impurity is heavier than the doping associated with just the letter identifying the impurity type without the “+” suffix. Conversely, the “−” symbol, when used as a suffix with an impurity type should be interpreted that the doping concentration of that impurity is lighter than the doping associated with just the letter identifying the impurity type without the “−” suffix.

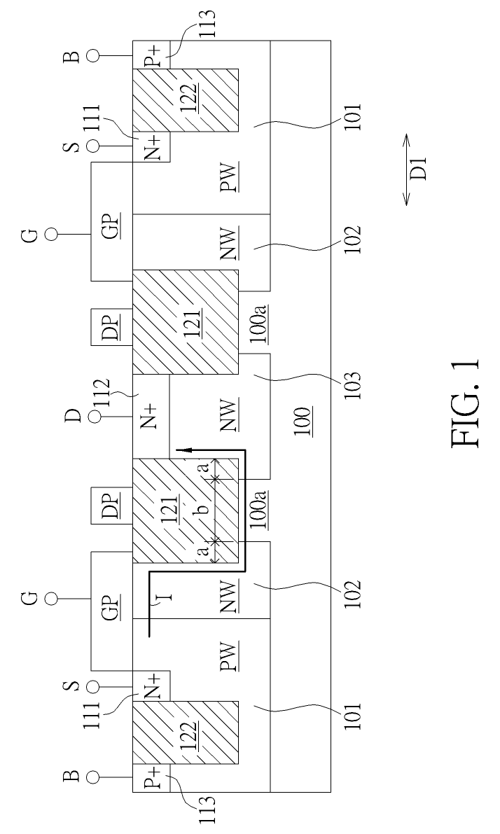

Referring first to FIG. 1, it illustrates a cross-sectional view of a laterally diffused metal-oxide semiconductor (referred hereinafter as LDMOS) device, in accordance with an embodiment of the present invention. As depicted in the figure, the LDMOS device of the present invention is fabricated on a semiconductor substrate 100. For example, in the case of an N-type LDMOS, the semiconductor substrate 100 can be a P-type semiconductor substrate, which is formed by lightly doping a P-type dopant (P-, e.g., boron (B)) into a single-crystal silicon substrate. Alternatively, the semiconductor substrate 100 can be of other silicon-based materials, such as a silicon-on-insulator (SOI) substrate, or substrates with other doping types, without being limited thereto. Notably, the semiconductor substrate 100 shown in FIG. 1 may also take the form of a fin structure, thereby enabling the construction of a fin field-effect transistor (FinFET). In the embodiment, the semiconductor substrate 100 is formed with a first well 101, a second well 102, and a third well 103, wherein the first well 101 is adjacent to the second well 102 along a first direction D1, with the two wells having distinct doping types. The second well 102 and the third well 103 are separated by a first shallow trench isolation (STI) 121 formed on the semiconductor substrate 100. Both the second and third wells 102, 103 are in direct contact with the first STI 121 along the first direction D1, and they share the same doping type. The first STI 121 is typically composed of silicon oxide, which is deposited in a recessed portion of the semiconductor substrate 100. In certain embodiments, the first STI 121 may alternatively be replaced by a field oxide layer.

In the case of an N-type LDMOS, the first well 101, the second well 102, and the third well 103 can be a P-type well (PW), an N-type well (NW) and another N-type well (NW), respectively, wherein the P-type well (PW) can be formed by moderately doping a P-type dopant (e.g., boron (B)) into the semiconductor substrate 100, with a doping concentration higher than that of the P-type semiconductor substrate 100, typically in the range of 10¹²-10¹⁴ cm⁻³, and a depth between 2000 Å and 3000 Å. The function of the P-type well (PW) is to effectively control current flow within the N-type LDMOS channel, thereby minimizing interference between different components and adjusting the threshold voltage of the NMOS. The N-type well (NW) is formed by moderately doping an N-type dopant (e.g., phosphorus (P), arsenic (As)) into the semiconductor substrate 100, with a doping concentration around 10¹²–10¹⁴ cm⁻³ and a depth between 2000 Å and 3000 Å. The N-type second well 102, the third well 103 and the adjacent semiconductor substrate 100 in the figure can be regarded as the drift region of the LDMOS. These regions form both lateral and vertical PN junctions with the neighboring P-type semiconductor substrate 100 and/or P-type well (PW). Therefore, during high-voltage operation, the N-type drift region can be fully depleted before reaching the critical breakdown voltage at the lateral PN junction, reducing the surface electric field (RESURF) and significantly enhancing the breakdown voltage at the drain terminal. Furthermore, the presence of the first STI 121 helps to prevent breakdown caused by the electric field concentration at the surface of drift region at the end of the channel.

Referring again to FIG. 1, in this embodiment, a gate pattern GP and a dummy pattern DP are formed on the semiconductor substrate 100, wherein the gate pattern GP vertically overlaps with both the first well 101 and the second well 102, and may partially overlap with the first STI 121, while the dummy pattern DP is positioned directly atop of the first STI 121. Both the gate pattern GP and the dummy pattern DP are typically composed of polysilicon. A gate oxide layer (not shown) may also be interposed between the gate pattern GP, dummy pattern DP and the semiconductor substrate 100. The gate pattern GP is electrically connected to a gate terminal G, allowing it to receive a gate voltage, while the dummy pattern DP serves as a dummy element, not connected to any voltage. On the other hand, the semiconductor substrate 100 also forms source doped region 111, drain doped region 112 and base doped region 113, which function as the terminals of the LDMOS device. The source doped region 111 is formed in the first well 101 on one side of the gate pattern GP along the first direction D1, the drain doped region 112 is located in the third well 103, while the base doped region 113 is located in the first well 101 outside of the source doped region 111 along the first direction D1. In this embodiment, the source doped region 111 and the drain doped region 112 are N-type heavily doped regions (N+), with doping concentrations higher than that of the N-type well (NW). The base doped region 113 is a P-type heavily doped region (P+), with a doping concentration higher than that of the P-type well (PW). The source doped region 111 is electrically connected to a source terminal S, serving as the current input, while the drain doped region 112 is electrically connected to a drain terminal D, serving as the current output. The base doped region 113 is electrically connected to the base terminal B, which acts as the pick-up terminal for the first well 101. During operation, the drain terminal D is connected to the device's operating voltage (V_{DD}), while the source terminal S and the base terminal B are commonly connected to a reference voltage (V_{SS}), such as ground voltage (GND), which can range from 0 to V_{DD}. The gate terminal G is connected to the circuit's supply voltage (V_{CC}), but not limited thereto. Additionally, in certain embodiments, the source doped region 111 and the base doped region 113 may be separated by a second STI 122 formed in the first well 101, reducing parasitic capacitance and current and preventing interference between the source and base regions. Specifically, the second STI 122 is positioned between the base doped region 113 and the source doped region 111, with both sides in direct contact with the base doped region 113 and the source doped region 111, respectively. In certain embodiments, the second STI 122 can alternatively be replaced by a field oxide layer.

Referring again to FIG. 1, it is noteworthy that in the prior art, the N-type well in the LDMOS drift region is a single well, meaning that the STI for the LDMOS thick oxide layer is formed directly on the N-type well, and the N-type well is not divided into two separate N-type wells (NW, i.e., second well 102 and third well 103) as shown in FIG. 1 of the present invention. With this configuration, it can be seen that in the embodiment of the present invention, the bottom of the first STI 121 comes into direct contact with a native region 100a of the semiconductor substrate 100. The native region 100a in the text refers to a portion of the semiconductor substrate 100 that shares the same doping concentration as the semiconductor substrate 100 itself and has not undergone further doping to form a well. Moreover, in this embodiment, the dummy pattern DP located on the semiconductor substrate 100 may overlap or completely overlap with the native region 100a in the vertical direction. With this configuration, it can be seen that when the gate is turned on, the signal current (I) from the source terminal S flows through the first well 101, the second well 102, the native region 100a and the third well region 103 to the drain terminal D. Since the signal current (I) flows through the low-conductivity native region 100a, this arrangement significantly enhances the breakdown voltage (BVD) of the LDMOS, potentially increasing it from 12V to 15V, which is one of the notable advantages of the present invention. Furthermore, the embodiment of the present invention allows for fine-tuning of the breakdown voltage by adjusting the distance (a) between the native region 100a and the adjacent N-type well (NW) in the first direction D1, as well as the width (b) of the native region 100a in the first direction D1, which is another advantage of the present invention. The distance (a) is determined by the cross-sectional profile of the two N-type wells (NW), typically ranging from 0.4 μm to 1 μm. Additionally, the dummy pattern DP located on the first STI 121 can also modify the electric field distribution around the first STI 121, further enhancing the breakdown voltage. This effect is especially pronounced when the dummy pattern DP completely overlaps with the underlying native region 100a, providing yet another significant benefit of the present invention.

Furthermore, it is noteworthy that the LDMOS device described in the text can adopt a fingered configuration. For instance, in this embodiment, the third well 103, the drain doped region 112 and the drain terminal D are shared by two LDMOS devices, forming a common drain. In alternative embodiments, the drain doped region 112 and the drain terminal D may be shared by more than two LDMOS devices, without limitation. This design improves the efficiency, thermal management, frequency response, linearity and gain of the device, resulting in improved performance in high-frequency and high-power applications.

Additionally, the LDMOS of the present invention can also be a P-type LDMOS. In such a configuration, the first well 101, second well 102, and third well 103 will be N-type well (NW), P-type well (PW) and another P-type well (PW), respectively, while the source doped region 111, drain doped region 112 and base doped region 113 will be P-type heavily doped regions (P+), P-type heavily doped regions (P+), and N-type heavily doped regions (N+), respectively.

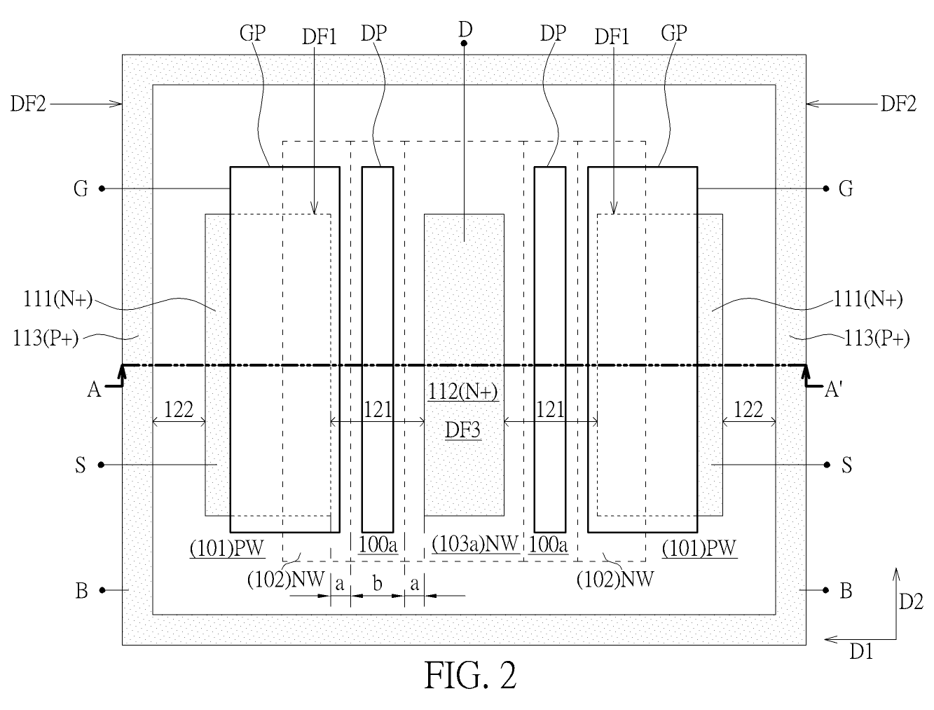

Now referring to FIG. 2, which illustrates the layout diagram of an LDMOS according to an embodiment of the present invention. The aforementioned FIG. 1 depicts the cross-sectional view taken along section line A-A' in FIG. 2. As illustrated in FIG. 2, the layout includes a first diffusion region DF1, a second diffusion region DF2 and a third diffusion region DF3, wherein the first diffusion region DF1 includes a portion covered by the gate pattern GP (as indicated by the dashed box) and a portion not covered by the gate pattern GP (corresponding to the source doped region 111 (N+)). The second diffusion region DF2 is the surrounding base doped region 113 (P+), and the third diffusion region DF3 forms the central drain doped region 112 (N+). In this embodiment, the surface area of the substrate between the first diffusion region DF1, second diffusion region DF2 and third diffusion region DF3 defines a shallow trench isolation, which consists of the first STI 121 and the second STI 122, wherein the first STI 121 is located between the first diffusion region DF1 and the third diffusion region DF3, while the second STI 122 lies between the first diffusion region DF1 and the second diffusion region DF2.

Referring again to FIG. 2, in this embodiment, the second well 102, the native region 100a of the substrate, the third well 103, the source doped region 111, the drain doped region 112, the gate pattern GP and the dummy pattern DP all exhibit elongated shapes. These elements are arranged along the first direction D1, with their major axes extending in the second direction D2, which is preferably perpendicular to the first direction D1. The first well 101 (PW) surrounds the second well 102 (NW), the native region 100a of the substrate and the third well 103 (NW). The base doped region 113 encircles the second STI 122, which may cover the layout area of multiple LDMOS devices. In this embodiment, the width of the dummy pattern DP in the first direction D1 is approximately 0.12 μm, and the distance between the dummy pattern DP and the gate pattern GP in the first direction D1 is approximately 0.2 μm.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A lateral diffusion metal-oxide semiconductor device, comprising:
a semiconductor substrate, comprising a first well, a second well and a third well, wherein the first well and the second well are adjacent to each other in a first direction and have different doping types;
a first shallow trench isolation, positioned in the semiconductor substrate and separating the second well from the third well, and both the second well and the third well share the same doping type, wherein the first shallow trench isolation directly contacts both the second well and the third well on either side in the first direction, with a bottom of the first shallow trench isolation being in direct contact with a native region of the semiconductor substrate;
a gate pattern, positioned on the semiconductor substrate and overlaps both the first well and the second well in a vertical direction;
a dummy pattern, positioned atop the first S shallow trench isolation;
a source doped region, positioned in the first well on one side of the gate pattern; and
a drain doped region, positioned on the third well.

2. The lateral diffusion metal-oxide semiconductor device of claim 1, wherein the dummy pattern overlaps the native region in the vertical direction.

3. The lateral diffusion metal-oxide semiconductor device of claim 1, wherein the gate pattern overlaps the first shallow trench isolation structure in the vertical direction.

4. The lateral diffusion metal-oxide semiconductor device of claim 1, further comprising a base doped region positioned in the first well outside the source doped region.

5. The lateral diffusion metal-oxide semiconductor device of claim 4, further comprising a second shallow trench isolation positioned in the first well and between the base doped region and the source doped region, wherein the second shallow trench isolation directly contacts both the base doped region and the source doped region on either side in the first direction.

6. The lateral diffusion metal-oxide semiconductor device of claim 4, wherein the lateral diffusion metal-oxide semiconductor device is an N-type lateral diffusion metal-oxide semiconductor device, the semiconductor substrate is a P-type semiconductor substrate, the first well is a P-type well, the second well and the third well are N-type wells, the source doped region and the drain doped region are heavily doped N-type regions, and the base doped region is a heavily doped P-type region.

7. The lateral diffusion metal-oxide semiconductor device of claim 4, wherein the lateral diffusion metal-oxide semiconductor device is a P-type LDMOS, the first well is an N-type well, and the second well and the third well are P-type wells, with the source doped region and drain doped region being heavily doped P-type regions, and the base doped region being a heavily doped N-type region.

8. The lateral diffusion metal-oxide semiconductor device of claim 1, wherein a material of the gate pattern and the dummy pattern is polysilicon.

9. The lateral diffusion metal-oxide semiconductor device of claim 1, wherein the drain doped region and the third well are shared by other lateral diffusion metal-oxide semiconductor devices.
